(19) United States
(12) Patent Application Publication
(10) Pub. No.: US 2017/0346001 A1
(43) Pub. Date: Nov. 30, 2017

(54) METHOD OF MANUFACTURING MAGNETORESISTIVE DEVICE AND MAGNETORESISTIVE DEVICE MANUFACTURING SYSTEM

(71) Applicant: TOKYO ELECTRON LIMITED, Tokyo (JP)

(72) Inventors: Takuya KUBO, Tokyo (JP); Song yun KANG, Tokyo (JP)

(73) Assignee: TOKYO ELECTRON LIMITED, Tokyo (JP)

(21) Appl. No.: 15/605,553

(22) Filed: May 25, 2017

(30) Foreign Application Priority Data
May 31, 2016 (JP) 2016-108937

(51) Int. Cl. H01L 43/12; H01L 43/08

(52) U.S. Cl. CPC H01L 43/12; H01L 43/08

(57) ABSTRACT

A method of manufacturing a magnetoresistive device according to an embodiment includes: forming an underlying film including silicon, oxygen, and carbon, on a substrate; performing plasma ashing on the underlying film by using plasma of an oxygen-containing gas; forming a multilayer film including a metal layer and a magnetic layer, on the underlying film subjected to ashing; and performing plasma etching on the multilayer film by using plasma of a hydrogen-containing gas.

This application is based on and claims the benefit of priority from Japanese Patent Application No. 2016-108937 filed on May 31, 2016, the entire contents of which is incorporated herein by reference.

Exemplary embodiments in this disclosure relate to a method of manufacturing a magnetoresistive device and a magnetoresistive device manufacturing system.

### BACKGROUND

In manufacture of electronic devices, plasma etching is used in order to form a microstructure in a workpiece. In the plasma etching, there are etching mainly using a reaction by active species and sputter etching mainly using ion bombardment.

In manufacture of a magnetoresistive device such as a magnetic random access memory (MRAM) which is one of electronic devices, plasma etching is performed on a multilayer film which includes a metal layer and a magnetic layer. The multilayer film includes a material which is hard to be etched, and therefore, sputter etching is used for plasma etching on the multilayer film. The sputter etching on such a multilayer film is disclosed in Japanese Patent Application Laid-Open Publication No. 2015-18885. In this literature, there is described sputter etching using an etching gas which includes hydrogen.

### SUMMARY

In one aspect, a method of manufacturing a magnetoresistive device is provided. The method of manufacturing a magnetoresistive device includes: forming an underlying film including silicon, oxygen, and carbon, on a substrate; performing plasma ashing on the underlying film by using plasma of an oxygen-containing gas; forming a multilayer film including a metal layer and a magnetic layer, on the underlying film subjected to ashing; and performing plasma etching on the multilayer film by using plasma of a hydrogen-containing gas.

In another aspect, a magnetoresistive device manufacturing system is provided. The magnetoresistive device manufacturing system includes: a transfer module having a transfer chamber capable of being depressurized and a transfer apparatus provided in the transfer chamber to transfer a substrate; a first processing module configured to form an underlying film including silicon, oxygen, and carbon, on the substrate; a second processing module configured to perform plasma ashing on the underlying film by using plasma of an oxygen-containing gas; a plurality of third processing modules configured to form a multilayer film including a metal layer and a magnetic layer, a fourth processing module configured to perform plasma etching on the multilayer film by using plasma of a hydrogen-containing gas; and a controller configured to control the first processing module, the second processing module, the plurality of third processing modules, and the fourth processing module, wherein the first processing module, the second processing module, the plurality of third processing modules, and the fourth processing module are connected to the transfer module, and the controller is configured to control the transfer apparatus, the first processing module, the second processing module, the plurality of third processing modules, and the fourth processing module so as to form the underlying film on the substrate, perform the plasma ashing on the underlying film, form the multilayer film on the underlying film subjected to ashing, and perform the plasma etching on the multilayer film, and control the transfer apparatus so as to transfer a workpiece having the underlying film subjected to ashing to a processing module for forming a lowermost layer of the multilayer film, among the plurality of third processing modules, through only a depressurized space including the transfer chamber, after the plasma ashing.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a flowchart showing a method of manufacturing a magnetoresistive device according to an exemplary embodiment.

FIG. 2 is a diagram illustrating an underlying film formed on a substrate in a step ST1 shown in FIG. 1.

FIG. 3 is a diagram showing plasma ashing in a step ST2 shown in FIG. 1.

FIG. 4 is a diagram illustrating a workpiece made in a step ST3 shown in FIG. 1.

FIG. 5 is a diagram showing plasma etching in a step ST4 shown in FIG. 1.

FIG. 6 is a diagram illustrating a multilayer film after execution of the step ST4 shown in FIG. 1.

FIG. 7 is a diagram schematically showing a magnetoresistive device manufacturing system according to an exemplary embodiment.

FIG. 8 is a diagram illustrating a plasma processing apparatus which can be used as a second processing module.

FIG. 9 is a diagram illustrating a sputtering apparatus which can be used as a third processing module.

FIGS. 10A and 10B are plan views showing a shutter of the sputtering apparatus as viewed from the stage side.

FIG. 11 is a diagram illustrating a plasma processing apparatus which can be used as a fourth processing module.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

The above-described multilayer film described in Japanese Patent Application Laid-Open Publication No. 2015-18885 is formed on an underlying film formed on a substrate. The underlying film is an insulating film including silicon, oxygen, and carbon. If sputter etching is performed on the multilayer film formed on such an underlying film by using plasma of a hydrogen-containing gas, peeling and/or cracking of the multilayer film may occur on the underlying film. Such peeling and/or cracking of the multilayer film causes a manufacturing defect of an electronic device and deteriorates the yield of the electronic device. Therefore, in plasma etching on the multilayer film, it is necessary to suppress peeling and/or cracking of the multilayer film.

In one aspect, a method of manufacturing a magnetoresistive device is provided. The method of manufacturing a magnetoresistive device includes: forming an underlying film including silicon, oxygen, and carbon, on a substrate; performing plasma ashing on the underlying film by using plasma of an oxygen-containing gas; forming a multilayer film including a metal layer and a magnetic layer, on the underlying film subjected to ashing; and performing plasma etching on the multilayer film by using plasma of a hydrogen-containing gas.

A cause of the peeling and/or cracking of the multilayer film due to the sputter etching using plasma of a hydrogen-containing gas is presumed as follows. Since the underlying film includes carbon, organic impurities which include carbon are present at the interface between the underlying film and the multilayer film. When the active species of hydrogen which is used for the sputter etching react with the organic impurities, a gas of a reaction product is generated in the interface. This gas expands to apply large stress to the multilayer film. As a result, it is presumed that the peeling and/or cracking of the multilayer film occurs.

In the manufacturing method according to the aspect, since the plasma ashing is performed on the underlying film by using the plasma of an oxygen-containing gas, the amount of organic impurities in a portion including the surface of the underlying film is reduced. Therefore, generation of the above-described gas is suppressed. As a result, in the plasma etching on the multilayer film, the peeling and/or cracking of the multilayer film is suppressed.

In one exemplary embodiment, the underlying film is formed by a chemical vapor deposition method using a gas containing silicon and carbon.

In one exemplary embodiment, the gas containing silicon and carbon includes tetraethoxysilane or methylsilane.

In one exemplary embodiment, the hydrogen-containing gas includes at least one of H₂, H₂O, a hydrocarbon, an alcohol, a ketone, an aldehyde, and a carboxylic acid.

In one exemplary embodiment, the metal layer includes ruthenium or platinum.

In another aspect, a magnetoresistive device manufacturing system is provided. The magnetoresistive device manufacturing system includes: a transfer module having a transfer chamber capable of being depressurized and a transfer apparatus provided in the transfer chamber to transfer a substrate; a first processing module configured to form an underlying film including silicon, oxygen, and carbon, on the substrate; a second processing module configured to perform plasma ashing on the undelayer film by using plasma of an oxygen-containing gas; a plurality of third processing modules configured to form a multilayer film including a metal layer and a magnetic layer, a fourth processing module configured to perform plasma etching on the multilayer film by using plasma of a hydrogen-containing gas; and a controller configured to control the first processing module, the second processing module, the plurality of third processing modules, and the fourth processing module, in which the first processing module, the second processing module, the plurality of third processing modules, and the fourth processing module are connected to the transfer module, and the controller is configured to control the transfer apparatus, the first processing module, the second processing module, the plurality of third processing modules, and the fourth processing module so as to form the underlying film on the substrate, perform the plasma ashing on the underlying film, form the multilayer film on the underlying film subjected to ashing, and perform the plasma etching on the multilayer film, and control the transfer apparatus so as to transfer a workpiece having the underlying film subjected to ashing to a processing module for forming a lowermost layer of the multilayer film, among the plurality of third processing modules, through only a depressurized space including the transfer chamber, after the plasma ashing.

Hereinafter, various embodiments will be described in detail with reference to the drawings. In the drawings, identical or corresponding parts are denoted by the same reference symbols.

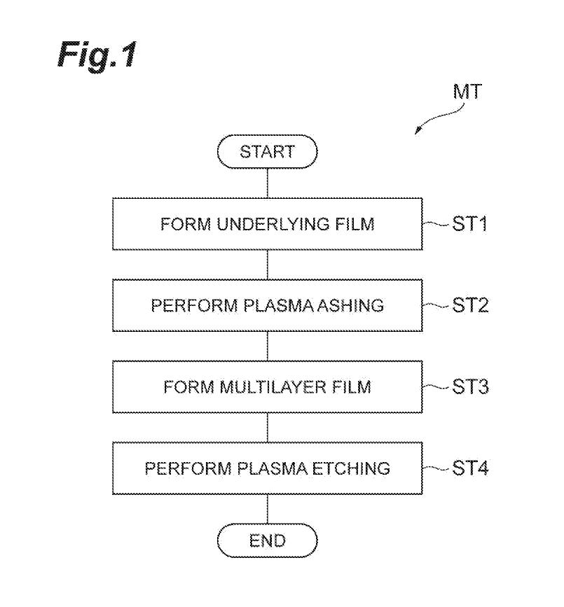

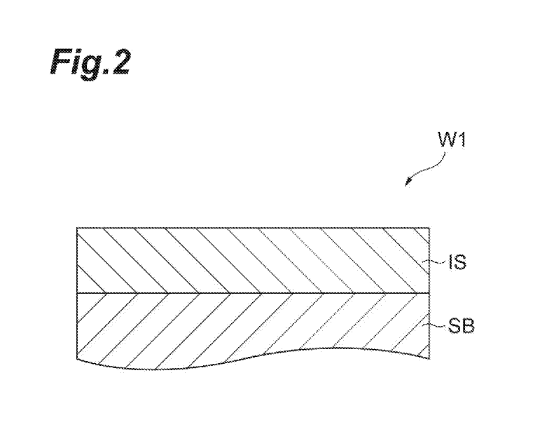

FIG. 1 is a flowchart showing a method of manufacturing a magnetoresistive device according to one exemplary embodiment. A magnetoresistive device manufacturing method MT shown in FIG. 1 includes a step ST1 to a step ST4. The manufacturing method MT is started from the step ST1. FIG. 2 is a diagram illustrating a underlying film which is formed on a substrate in the step ST1. In the step ST1, a underlying film IS is formed on a substrate SB, as shown in FIG. 2. The underlying film IS is an insulating film and includes silicon, oxygen, and carbon. That is, the underlying film IS is formed of a silicon oxide and can include carbon. The undelayer film IS is formed by, for example, a chemical vapor deposition (CVD) method. In the CVD method, for example, a gas containing silicon and carbon is used. This gas can include tetraethoxysilane (TEOS) or methylsilane.

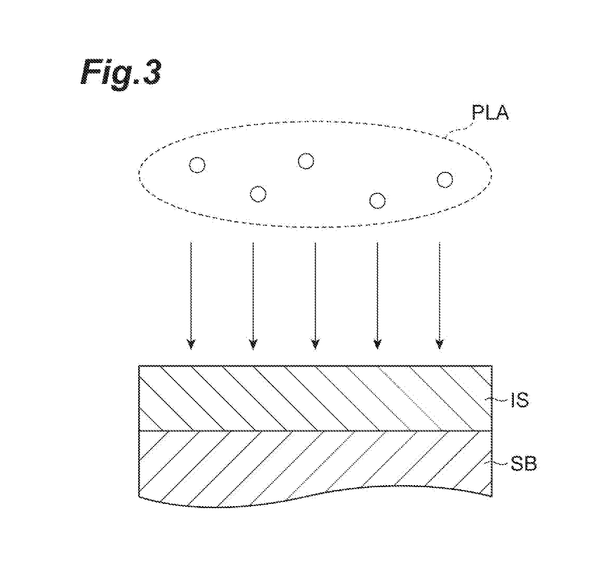

In the subsequent step ST2, plasma ashing is performed on the underlying film IS by using plasma of an oxygen-containing gas. FIG. 3 is a diagram showing the plasma ashing in the step ST2. In FIG. 3, a circular figure shows the active species of oxygen. In the step ST2, plasma PLA of an oxygen-containing gas is generated, and the underlying film IS is irradiated with the active species of the oxygen from the plasma PLA. Accordingly, the amount of carbon in a portion including the surface of the underlying film IS is reduced.

In the subsequent step ST3, a multilayer film ML which includes a metal layer and a magnetic layer is formed on the underlying film IS subjected to ashing. Further, in the step ST3, a mask MK is formed on the multilayer film ML. The multilayer film ML and the mask MK are formed by, for example, sputtering.

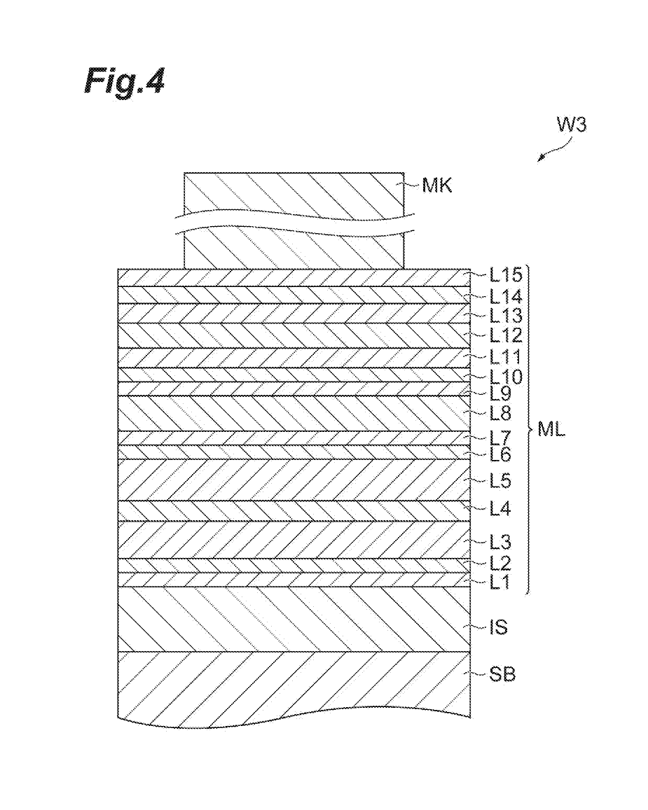

FIG. 4 is a diagram illustrating a workpiece which is made in the step ST3. As shown in FIG. 4, a third workpiece W3 which is made in the step ST3 includes the multilayer film ML and the mask MK. The multilayer film ML has a plurality of layers. For example, as shown in FIG. 4, the multilayer film ML has fifteen layers; a first layer L1 to a fifteenth layer L15.

The first layer L1 is a lowermost layer, that is, a layer provided closest to the underlying film IS and is formed of Ta. The second layer L2 is provided on the first layer L1 and formed of Ru. The third layer L3 is provided on the second layer L2 and formed of Ta. The fourth layer L4 is provided on the third layer L3 and formed of Pt. The fifth layer L5 is provided on the fourth layer L4 and formed of Pt and Co. The sixth layer L6 is provided on the fifth layer L5 and formed of Co. The seventh layer L7 is provided on the sixth layer L6 and formed of Ru. The eighth layer L8 is provided on the seventh layer L7 and formed of Pt and Co. The ninth layer L9 is provided on the eighth layer L8 and formed of Co. The tenth layer L10 is provided on the ninth layer L9 and formed of Ta. The eleventh layer L11 is provided on the tenth layer L10 and formed of CoFeB. The twelfth layer L12 is provided on the eleventh layer L11 and formed of MgO. The thirteenth layer L13 is provided on the twelfth layer L12 and formed of CoFeB. The fourteenth layer L14 is provided on the thirteenth layer L13 and formed of Ta. The fifteenth layer L15 is provided on the fourteenth layer L14 and formed of Ru. Each of the fifth layer L5 and the eighth layer L8 has a structure in which a Pt thin film and a Co thin film are alternately laminated. Specifically, the fifth layer L5 has a structure in which six layers of Pt thin films and six layers of Co thin films are alternately laminated, and the eighth layer L8 has a structure in which two layers of Pt thin films and two layers of Co thin films are alternately laminated. In the structure, each of the first layer L1, the second layer L2, the third layer L3, the fourth layer LA, the seventh layer L7, the tenth layer L10, the fourteenth layer 14, and the fifteenth layer L15 is a metal layer, and each of the fifth layer L5, the sixth layer L6, the eighth layer L8, the ninth layer L9, the eleventh layer L11, and the thirteenth layer L13 is a magnetic layer.

The first layer L1 and the second layer L2 of the multilayer film ML configure a lower electrode. The third layer L3 and the fourth layer L4 are seed layers for growing a film thereon. The fifth layer L5 and the sixth layer L6 configure an antiferromagnetic layer. The seventh layer L7 is used as a spacer between the antiferromagnetic layer and an upper magnetization fixed layer. The eighth layer L8, the ninth layer L9, the tenth layer L10, and the eleventh layer L11 configure a magnetization fixed layer. The twelfth layer L12 is a tunnel barrier layer, and the thirteenth layer L13 is a magnetization free layer. The fourteenth layer L14 and the fifteenth layer L15 configure an upper electrode. Further, the magnetization fixed layer, the tunnel barrier layer, and the magnetization free layer configure a magnetic tunnel junction (MTJ).

The thickness of each layer of the multilayer film ML is exemplified. The thickness of the first layer L1 is 5 nm, the thickness of the second layer L2 is 5 nm, the thickness of the third layer L3 is 10 nm, the thickness of the fourth layer L4 is 5 nm, the thickness of the fifth layer L5 is 4.8 nm, the thickness of the sixth layer L6 is 0.5 nm, the thickness of the seventh layer L7 is 0.9 nm, the thickness of the eighth layer L8 is 1.6 nm, the thickness of the ninth layer L9 is 0.5 nm, the thickness of the tenth layer L10 is 0.4 nm, the thickness of the eleventh layer L11 is 1.2 nm, the thickness of the twelfth layer L12 is 1.3 nm, the thickness of the thirteenth layer L13 is 1.6 nm, the thickness of the fourteenth layer L14 is 5 nm, and the thickness of the fifteenth layer L5 is 5 nm.

The mask MK is a mask fabricated from a metal-containing film. The metal-containing film is formed of, for example, Ta, TiN, or the like. The pattern of the mask MK can be formed by plasma etching.

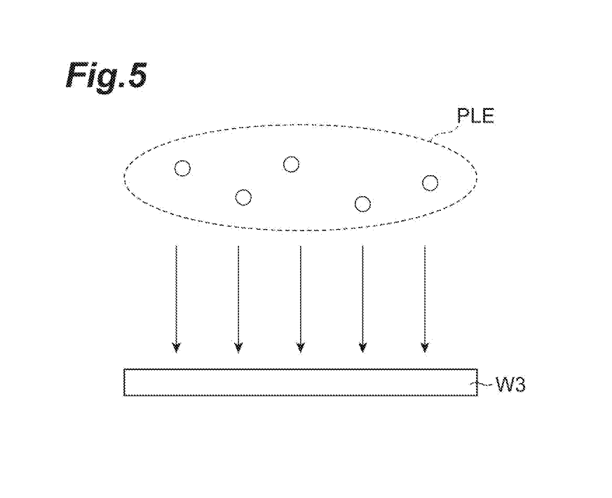

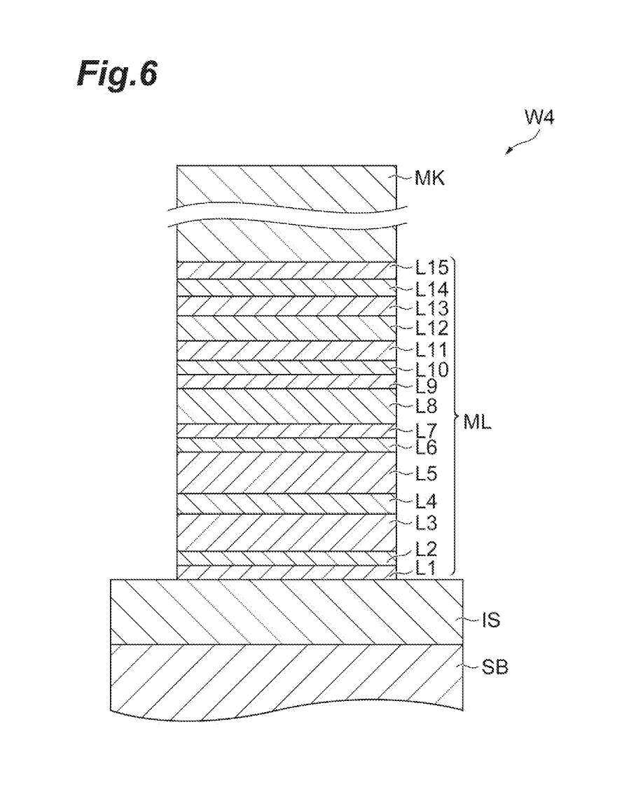

Referring to FIG. 1 again, in the step ST4, plasma etching is performed on the multilayer film ML by using plasma of a hydrogen-containing gas. The hydrogen-containing gas includes at least one of H₂, H₂O, a hydrocarbon, an alcohol, a ketone, an aldehyde, and a carboxylic acid. FIG. 5 is a diagram showing plasma etching in the step ST4. In FIG. 5, a circular figure shows ions which etch the multilayer film ML. In the step ST4, plasma PLE of a hydrogen-containing gas is generated, and ions from the plasma PLE are attracted to the multilayer film ML so as to collide with the multilayer film ML. In this way, sputter etching is performed on the multilayer film ML. FIG. 6 is a diagram illustrating the multilayer film after the execution of the step ST4. As shown in FIG. 6, in the plasma etching in the step ST4, the multilayer film ML is etched until the underlying film IS is exposed. The pattern of the mask MK is transferred to the multilayer film ML by the plasma etching in the step ST4.

As described above, the underlying film IS includes carbon, and therefore, when the multilayer film ML is formed on the underlying film IS without performing the plasma ashing in the step ST2, organic impurities which include carbon are left at the interface between the underlying film IS and the multilayer film ML. When the active species of hydrogen which is used for the sputter etching in the step ST4 react with the organic impurities, a gas of a reaction product is generated in the interface. This gas expands to apply large stress to the multilayer film. As a result, peeling and/or cracking of the multilayer film can occur. In the manufacturing method MT, the plasma ashing in the step ST2 is performed on the underlying film IS, and therefore, the amount of organic impurities in a portion including the surface of the underlying film IS is reduced. Therefore, generation of the gas is suppressed. As a result, in the plasma etching on the multilayer film ML, peeling and/or cracking of the multilayer film ML is suppressed.

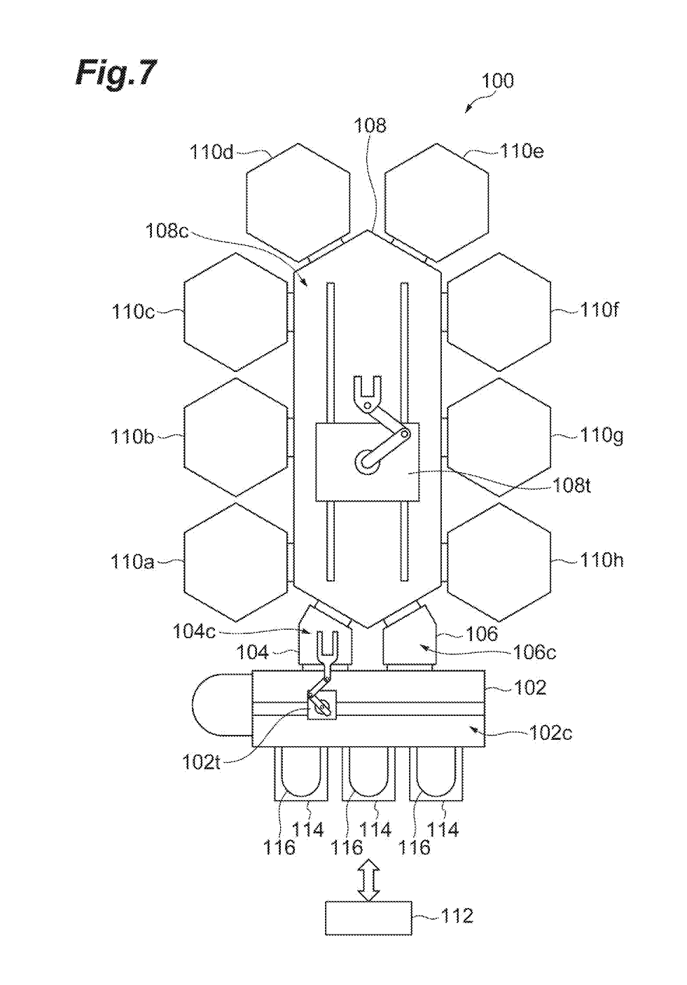

Hereinafter, a manufacturing system which can be used to implement the manufacturing method MT will be described with reference to FIG. 7. FIG. 7 is a diagram schematically showing a magnetoresistive device manufacturing system according to an exemplary embodiment. A manufacturing system 100 shown in FIG. 7 is provided with a loader module 102, load lock modules 104 and 106, a transfer module 108, a plurality of processing modules 110a to 110h, and a controller 112. Although the number of the plurality of processing modules 110a to 110h is eight in the manufacturing system 100 shown in FIG. 7, it may be arbitrary number.

The loader module 102 is an apparatus configured to transfer a workpiece in an atmospheric pressure environment. A plurality of tables 114 are attached to the loader module 102. Containers 116 capable of accommodating a plurality of workpieces therein are respectively mounted on the plurality of tables 114. The container 116 can be a FOUP (Front Opening Unified Pod).

The loader module 102 has a transfer apparatus 102t provided in a transfer chamber 102c inside thereof. The transfer apparatus 102t can include a robot arm configured to hold a workpiece and transfer the workpiece. The load lock module 104 and the load lock module 106 are connected to the loader module 102. The transfer apparatus 102t transfers the workpiece between the container 116 and the load lock module 104 or between the container 116 and the load lock module 106.

The load lock module 104 and the load lock module 106 respectively provide a chamber 104c and a chamber 106c for preliminary depressurization. The transfer module 108 is connected to the load lock module 104 and the load lock module 106. The transfer module 108 provides a transfer chamber 108c which can be depressurized, and the transfer chamber 108c has a transfer apparatus 108t inside thereof. The transfer apparatus 108t can include a robot arm configured to hold a workpiece and transfer the workpiece. The plurality of processing modules 110a to 110h are connected to the transfer module 108. The transfer apparatus 108t of the transfer module 108 transfers the workpiece between either of the load lock module 104 or the load lock module 106 and any one of the plurality of processing modules 110a to 110h and between arbitrary two processing modules among the plurality of processing modules 110a to 110h.

The plurality of processing modules 110a to 110h include a first processing module 110a, a second processing module 110b, a plurality of third processing modules 110c to 110g, and a fourth processing module 110h. The first processing module 110a can be a module configured to form the underlying film IS on the substrate SB. The first processing module 110a can be, for example, a CVD apparatus. The second processing module 110b can be a module configured to perform plasma ashing on the underlying film IS. The second processing module 110b can be a plasma processing apparatus for plasma ashing. The plurality of third processing modules 110c to 110g can be modules configured to form the multilayer film ML which includes a metal layer and a magnetic layer. The plurality of third processing modules 110c to 110g can also include a module configured to form the mask.

Each of the plurality of third processing modules 110c to 110g can be a sputtering apparatus. Each sputtering apparatus is configured to form one or more target substance films. When the manufacturing system 100 is configured to form the multilayer film ML shown in FIG. 4, each of the plurality of sputtering apparatuses has one or more corresponding targets among a Ta target, a Ru target, a Pt target, a Co target, a CoFeB target, and a magnesium oxide (MgO) target. In an example, each of the plurality of sputtering apparatuses can be a sputtering apparatus having four targets and performing sputtering of a constituent substance of a selected target among the four targets.

One of the plurality of sputtering apparatuses may have a Mg target instead of the MgO target. In having the Mg target, one of the plurality of third processing modules 110c to 110g can be an oxidation processing apparatus configured to oxidize a Mg film. The oxidation processing apparatus may be an apparatus which heats the Mg film in an oxygen atmosphere or may be a plasma processing apparatus which generates plasma of an oxygen gas. The plasma processing apparatus can be any plasma processing apparatus such as a capacitively coupled plasma processing apparatus, an inductively coupled plasma processing apparatus, or a plasma processing apparatus which generates plasma with surface waves such as microwaves.

The fourth processing module 110h can be a module for performing plasma etching on the multilayer film ML. The fourth processing module 110h can be a plasma processing apparatus for plasma etching.

The controller 112 is configured to control the transfer module 108, the first processing module 110a, the second processing module 110b, the plurality of third processing modules 110c to 110g, and the fourth processing module 110h. Further, the controller 112 is configured to further control the loader module 102. The controller 112 can be, for example, a computer device having a processor and a storage device such as a memory. In the storage device, a program for controlling each part of the manufacturing system 100 and recipe data for implementing the manufacturing method MT in the manufacturing system 100 are stored. The processor operates in accordance with the program and the recipe data stored in the storage device and outputs a control signal for controlling each part of the manufacturing system 100 to the each part.

In the implementation of the manufacturing method MT, the controller 112 controls the transfer apparatus 102t of the loader module 102 to transfer the substrate SB from the container 116 to either of the load lock module 104 or the load lock module 106. Subsequently, the controller 112 controls the transfer apparatus 108t of the transfer module 108 to transfer the substrate SB carried in either of the load lock module 104 or the load lock module 106 to the first processing module 110a. Then, the controller 112 controls the first processing module 110a to form the underlying film IS on the substrate SB. In this way, a first workpiece W1 shown in FIG. 2 is made.

Subsequently, the controller 112 controls the transfer apparatus 108t of the transfer module 108 to transfer the first workpiece W1 to the second processing module 110b. The first workpiece W1 is transferred from the first processing module 110a to the second processing module 110b through only the depressurized space which includes the transfer chamber 108c after the formation of the underlying film IS. Then, the controller 112 controls a plasma ashing apparatus of the second processing module 110b to perform plasma ashing on the underlying film IS. In this way, a second workpiece is made.

Subsequently, the controller 112 controls the transfer apparatus 108t of the transfer module 108 to transfer the second workpiece to the third processing module 110c among the plurality of third processing modules 110c to 110g. The third processing module 110c has a target for forming the first layer L1 that is the lowermost layer in the multilayer film ML. The second workpiece is transferred from the second processing module 110b to the third processing module 110c through only the depressurized space which includes the transfer chamber 108c after the plasma ashing.

Subsequently, in order to sequentially form each layer of the second layer L2 to the fifteenth layer L15 and the mask MK, the controller 112 controls the transfer apparatus 108t of the transfer module 108 and some third processing modules to be operated in the formation of each layer, among the plurality of third processing modules 110c to 110g. In this way, the third workpiece W3 is made. The controller 112 controls the transfer apparatus 108t of the transfer module 108 to transfer the workpiece between any two third processing modules through only the depressurized space which includes the transfer chamber 108c. When the third processing module has two or more targets for forming two successive layers among the multilayer film ML and the mask MK, it is unnecessary to transfer a workpiece between the formations of these two layers.

Subsequently, the controller 112 controls the transfer apparatus 108t of the transfer module 108 to transfer the third workpiece W3 to the fourth processing module 110h. The third workpiece W3 is transferred from the third processing module used for the previous processing to the fourth processing module 110h through only the depressurized space which includes the transfer chamber 108c. Then, the controller 112 controls the fourth processing module 110h to perform plasma etching for forming the pattern of the mask MK. Further, the controller 112 controls the fourth processing module 110h so as to perform plasma etching on the multilayer film ML.

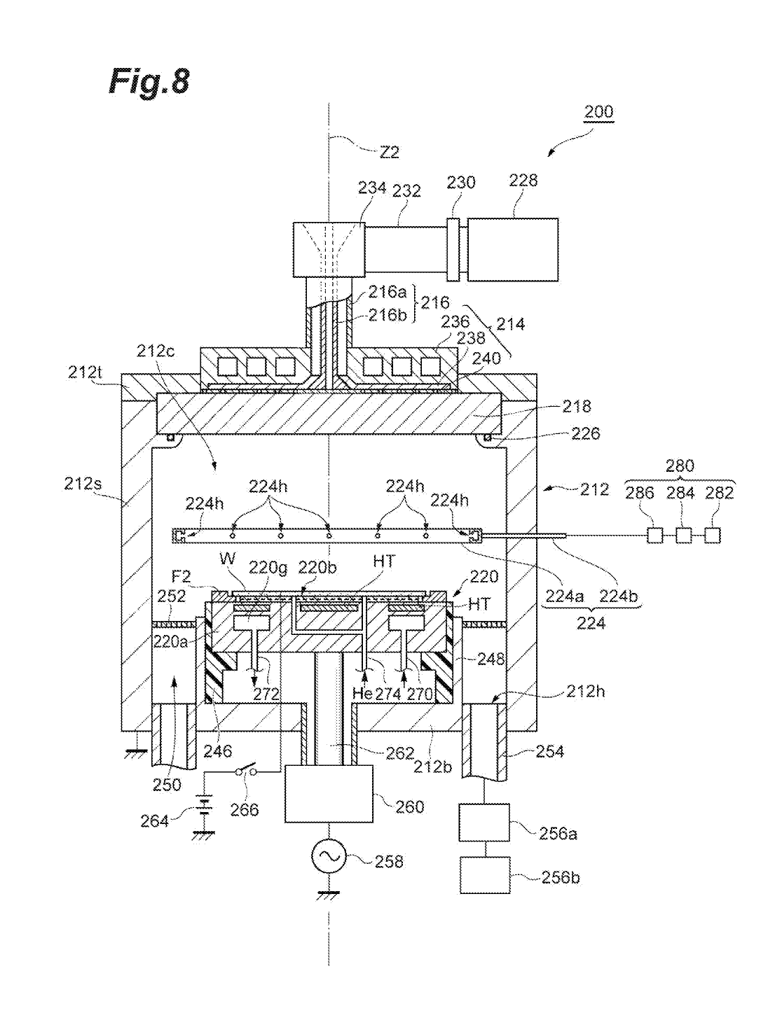

Hereinafter, an example of a plasma processing apparatus which can be used as the second processing module 110b of the manufacturing system 100 will be described. FIG. 8 is a diagram illustrating the plasma processing apparatus which can be used as the second processing module. A plasma processing apparatus 200 shown in FIG. 8 is a plasma processing apparatus which excites a gas by microwaves. The plasma processing apparatus 200 is provided with a chamber body 212.

The chamber body 212 provides its internal space as a chamber 212c. The chamber body 212 includes a side wall 212s, a bottom part 212b, and a top part 212t and has a substantially cylindrical shape. The center axis of the chamber body 212 substantially coincides with an axis Z2 extending in a vertical direction. The bottom part 212b is provided on the lower end side of the side wall 212s. An exhaust hole 212h is provided in the bottom part 212b. An upper end portion of the side wall 212s is open. The opening of the upper end portion of the side wall 212s is closed by a dielectric window 218. The dielectric window 218 is held between the upper end portion of the side wall 212s and the top part 212t. A sealing member 226 may be interposed between the dielectric window 218 and the upper end portion of the side wall 212s. The sealing member 226 may be, for example, an O-ring.

The plasma processing apparatus 200 is further provided with a stage 220. The stage 220 is provided below the dielectric window 218. The stage 220 includes a lower electrode 220a and an electrostatic chuck 220b.

The lower electrode 220a is supported by a support part 246. The support part 246 is formed of an insulating material. The support part 246 has a substantially cylindrical shape and extends upward from the bottom part 212b. Further, a conductive support part 248 is provided at the outer periphery of the support part 246. The support part 248 extends upward from the bottom part 212b of the chamber body 212 along the outer periphery of the support part 246. An annular exhaust path 250 is formed between the support part 248 and the side wall 212s.

A baffle plate 252 is provided at an upper portion of the exhaust path 250. A plurality of through-holes extending in a plate thickness direction are formed in the baffle plate 252. The exhaust path 250 is connected to an exhaust pipe 254 which provides the exhaust hole 212h, and an exhaust device 256b is connected to the exhaust pipe 254 through a pressure adjustor 256a. The exhaust device 256b has a vacuum pump such as a turbo molecular pump. The pressure adjustor 256a adjusts the displacement of the exhaust device 256b, thereby adjusting the pressure in the chamber 212c. The chamber 212c can be depressurized to a desired degree of vacuum by the pressure adjustor 256a and the exhaust device 256b. Further, a gas can be exhausted from the outer periphery of the stage 220 through the exhaust path 250 by the exhaust device 256b.

The lower electrode 220a is formed of a conductor such as aluminum and has a substantially disk shape. A high frequency power source 258 for RF bias is electrically connected to the lower electrode 220a through a matching unit 260 and a power-feeding rod 262. The high frequency power source 258 generates a high frequency wave, which is suitable for attracting ions and can be, for example, 13.65 MHz. The matching unit 260 accommodates a matching device configured to perform matching between impedance on the high frequency power source 258 side and impedance on the load side such as the lower electrode 220a, plasma, and the chamber body 212.

The electrostatic chuck 220b is provided on the lower electrode 220a. The electrostatic chuck 220b has an electrode built in a dielectric film. A direct-current power source 264 is connected to the electrode through a switch 266. When a direct-current voltage from the direct-current power source 264 is applied to the electrode of the electrostatic chuck 220b, the electrostatic chuck 220b generates a Coulomb's force and attracts a workpiece W to the electrostatic chuck 220b by the Coulomb's force, thereby holding the workpiece W. A focus ring F2 is disposed around the electrostatic chuck 220b.

A flow path 220g is formed in the interior of the lower electrode 220a. A coolant is supplied from a chiller unit to the flow path 220g through a pipe 270. The coolant supplied to the flow path 220g is returned to the chiller unit through a pipe 272. Further, a heater HT is built in the stage 220. In the plasma processing apparatus 200, the amount of heat generation of the heater HT and the temperature of the coolant are adjusted, whereby the temperature of the workpiece W is adjusted. Further, in the plasma processing apparatus 200, a heat transfer gas, for example, He gas, from a heat transfer gas supply unit is supplied between the upper surface of the electrostatic chuck 220b and the back surface of the workpiece W through a pipe 274.

The plasma processing apparatus 200 is further provided with an antenna 214, a coaxial waveguide 216, the dielectric window 218, a microwave generator 228, a tuner 230, a waveguide 232, and a mode converter 234. The microwave generator 228 generates a microwave having a frequency of, for example, 2.45 GHz. The microwave generator 228 is connected to an upper portion of the coaxial waveguide 216 through the tuner 230, the waveguide 232, and the mode converter 234. The coaxial waveguide 216 includes an outer conductor 216a and an inner conductor 216b. The outer conductor 216a has a cylindrical shape, and the center axis thereof substantially coincides with the axis Z2. A lower end of the outer conductor 216a is connected to an upper portion of a cooling jacket 236 having a conductive surface. The inner conductor 216b is provided inside the outer conductor 216a. The inner conductor 216b has a substantially cylindrical shape, and the center axis thereof substantially coincides with the axis Z2. A lower end of the inner conductor 216b is connected to a slot plate 240 of the antenna 214.

The antenna 214 is disposed in an opening formed in the top part 212t. The antenna 214 includes a dielectric plate 238 and the slot plate 240. The dielectric plate 238 is for shortening the wavelength of a microwave and has a substantially disk shape. The dielectric plate 238 is formed of, for example, quartz or alumina. The dielectric plate 238 is held between the slot plate 240 and the lower surface of the cooling jacket 236.

The slot plate 240 is made of metal and has a substantially disk shape. A plurality of slot pairs are formed in the slot plate 240. Each of the plurality of slot pairs includes two slot holes. The two slot holes penetrate the slot plate 240 in a plate thickness direction and have elongated hole shapes extending in directions intersecting each other. The plurality of slot pairs are arranged along one or more concentric circles centered on the axis Z2.

In the plasma processing apparatus 200, the microwave generated by the microwave generator 228 is propagated to the dielectric plate 238 through the coaxial waveguide 216 and applied from the slot hole of the slot plate 240 to the dielectric window 218. The dielectric window 218 has a substantially disk shape and is made of, for example, quartz or alumina. The dielectric window 218 is provided immediately below the slot plate 240. The dielectric window 218 transmits the microwave received from the antenna 214 and introduces the microwave into the chamber 212c. In this way, an electric field is generated immediately below the dielectric window 218.

The plasma processing apparatus 200 is further provided with an introduction part 224 and a gas supply system 280. The introduction part 224 includes an annular pipe 224a and a pipe 224b. The annular pipe 224a is provided in the chamber 212c so as to extend annularly in a circumferential direction with respect to the axis Z2. A plurality of gas injection holes 224h opened toward the axis Z2 are formed in the annular pipe 224a. The pipe 224b is connected to the annular pipe 224a and extends to the outside of the chamber body 212.

The gas supply system 280 includes a gas source group 282, a flow rate controller group 284, and a valve group 286. The gas source group 282 includes one or more gas sources of an oxygen-containing gas. For example, the gas source group 282 can include a source of an oxygen gas (O₂ gas) and a source of a rare gas (for example, Ar gas). The flow rate controller group 284 includes one or more flow rate controllers such as mass flow controllers. The valve group 286 includes one or more valves. Each of one or more gas sources of the gas source group 282 is connected to the pipe 224b through a corresponding flow rate controller of the flow rate controller group 284 and a corresponding valve of the valve group 286.

In the plasma processing apparatus 200, an oxygen-containing gas from the gas source group 282 is supplied to the chamber 212c. Further, the chamber 212c is depressurized by the pressure adjustor 256a and the exhaust device 256b. Further, an electric field is formed by the microwaves introduced from the dielectric window 218 into the chamber 212c. The oxygen-containing gas is excited by such an electric field. In this way, plasma of the oxygen-containing gas is generated. Then, the workpiece W is processed by the active species of oxygen from the plasma. In this manner, the plasma processing apparatus 200 can perform the processing of the workpiece W with the active species of oxygen.

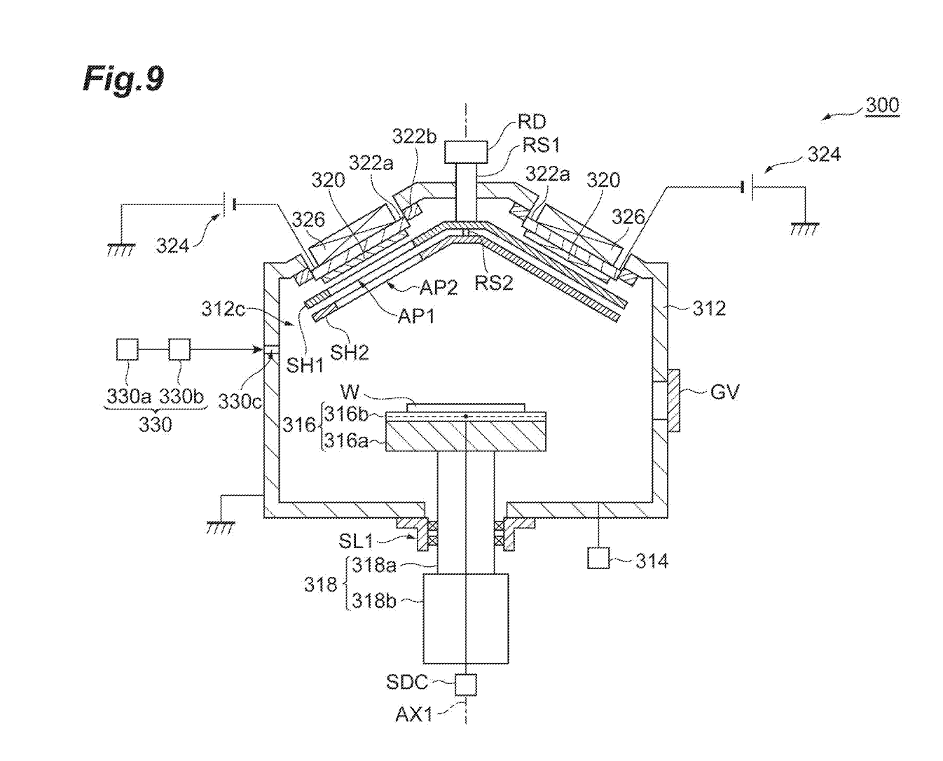

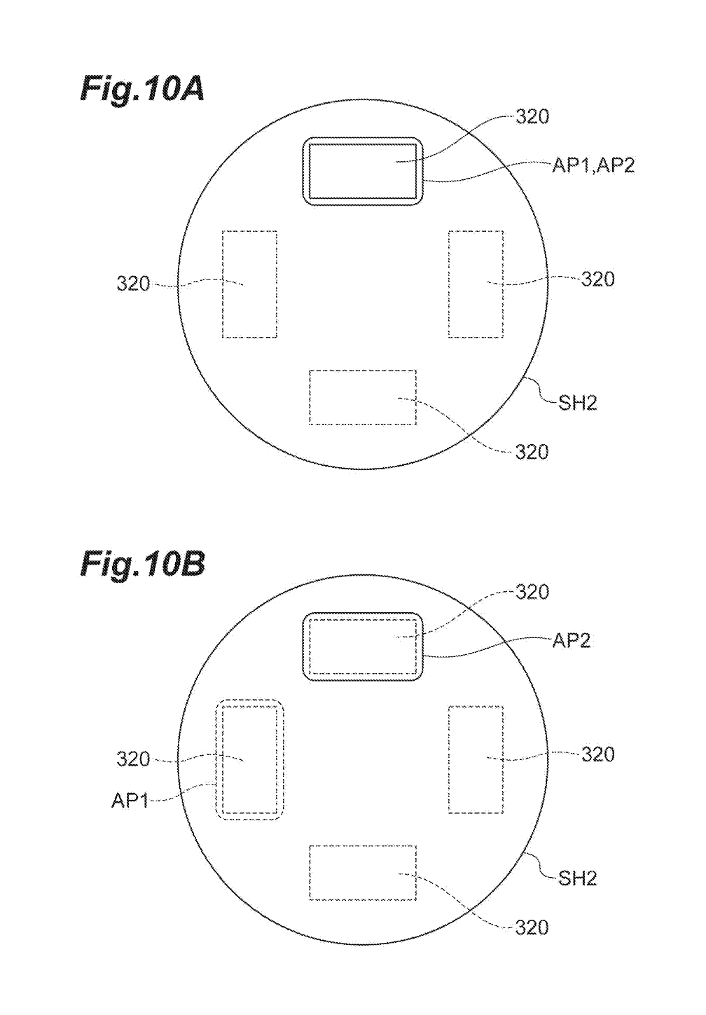

Hereinafter, a sputtering apparatus which can be used as each of the plurality of third processing modules 110c to 110g of the manufacturing system 100 will be described. FIG. 9 is a diagram illustrating the sputtering apparatus which can be used as the third processing module. FIGS. 10A and 10B are plan views showing a shutter of the sputtering apparatus as viewed from the stage side.

A sputtering apparatus 300 shown in FIG. 9 is provided with a chamber body 312. The chamber body 312 is formed of, for example, aluminum and connected to a ground potential. The chamber body 312 provides its internal space as a chamber 312c. An exhaust apparatus 314 configured to depressurize the chamber 312c is connected to a bottom part of the chamber body 312. The exhaust apparatus 314 can include, for example, a cryopump and a dry pump. Further, an opening for transfer of the workpiece W is formed in a side wall of the chamber body 312. For opening and closing of the opening, a gate valve GV is provided along the side wall of the chamber body 312.

A stage 316 is provided in the chamber body 312. The stage 316 can include a base part 316a and an electrostatic chuck 316b. The base part 316a is configured of, for example, aluminum and has a substantially disk shape.

The electrostatic chuck 316b is provided on the base part 316a. The electrostatic chuck 316b has an electrode built in a dielectric film. A direct-current power source SDC is connected to the electrode of the electrostatic chuck 316b. The workpiece W placed on the electrostatic chuck 316b is attracted to and held on the electrostatic chuck 316b by a Coulomb's force which is generated by the electrostatic chuck 316b.

The stage 316 is connected to a stage driving mechanism 318. The stage driving mechanism 318 includes a spindle 318a and a driving apparatus 318b. The spindle 318a is a substantially columnar member. The center axis of the spindle 318a substantially coincides with an axis AX1 extending along the vertical direction. The axis AX1 is an axis vertically passing through the center of the stage 316. The spindle 318a extends from immediately below the stage 316 to the outside of the chamber body 312 through the bottom part of the chamber body 312. A sealing member SL1 is provided between the spindle 318a and the bottom part of the chamber body 312. The sealing member SL1 seals the space between the bottom part of the chamber body 312 and the spindle 318a such that the spindle 318a can rotate and move up and down. The sealing member SL1 can be, for example, a magnetic fluid seal.

The stage 316 is coupled to an upper end of the spindle 318a, and the driving apparatus 318b is connected to a lower end of the spindle 318a. The driving apparatus 318b generates driving force for causing the rotation and the up-and-down movement of the spindle 318a. The stage 316 rotates around the axis AX1 as the spindle 318a is rotated by this driving force, and the stage 316 moves up and down as the spindle 318a moves up and down.

As shown in FIGS. 9, 10A, and 10B, four targets (cathode targets) 320 are provided above the stage 316. These targets 320 are arranged along an arc centered on the axis AX1.

Each of the targets 320 is held by a holder 322a made of metal. The holder 322a is supported on a top part of the chamber body 312 through an insulating member 322b. A power source 324 is connected to the target 320 through the holder 322a. The power source 324 applies a negative direct-current voltage to the target 320. The power source 324 may be a single power source which selectively applies voltage to the plurality of targets 320. Alternatively, the power source 324 may be a plurality of power sources respectively connected to the plurality of targets 320. Further, the power source 324 may be a high frequency power source.

In the sputtering apparatus 300, a magnet (a cathode magnet) 326 is provided outside the chamber body 312 so as to face a corresponding target 320 through the holder 322a.

Further, the sputtering apparatus 300 is provided with a gas supply unit 330 which supplies a gas to the chamber 312c. The gas supply unit 330 includes a gas source 330a, a flow rate controller 330b such as a mass flow controller, and a gas introduction part 330c. The gas source 330a is a source of a gas which is excited in the chamber 312c, and is a source of a rare gas (for example, Ar gas). The gas source 330a is connected to the gas introduction part 330c through the flow rate controller 330b. The gas introduction part 330c is a gas line for introducing the gas from the gas source 330a into the chamber 312c.

When a gas is supplied from the gas supply unit 330 to the chamber 312c and voltage is applied to the target 320 by the power source 324, the gas supplied to the chamber 312c is excited. Further, a magnetic field is generated in the vicinity of a corresponding target 320 by the magnet 326. In this way, plasma concentrates in the vicinity of the target 320. Then, positive ions in the plasma collide with the target 320, whereby a constituent substance of the target 320 is released from the target 320. In this way, a film is formed on the workpiece W.

Further, a shutter SH1 and a shutter SH2 are provided between the target 320 and the stage 316. The shutter SH1 extends to face the surface of the target 320. The shutter SH1 has, for example, a shape conforming to a conical surface with the axis AX1 as a center axis thereof. The shutter SH2 is interposed between the shutter SH1 and the stage 316. The shutter SH2 has, for example, a shape conforming to a conical surface with the axis AX1 as a center axis thereof and is provided along the shutter SH1 and to be spaced apart from the shutter SH1.

An opening AP1 is formed in the shutter SH1. A rotary shaft RS1 is coupled to a central portion of the shutter SH1. Further, an opening AP2 is formed in the shutter SH2. A rotary shaft RS2 is coupled to a central portion of the shutter SH2. The center axis of the rotary shaft RS1 and the center axis of the rotary shaft RS2 substantially coincide with the axis AX1. That is, the rotary shaft RS1 and the rotary shaft RS2 are provided coaxially. The rotary shaft RS1 and the rotary shaft RS2 extend to the outside of the chamber body 312 and are connected to a driving apparatus RD. The driving apparatus RD is configured to independently rotate the rotary shaft RS1 and the rotary shaft RS2 around the axis AX1. The shutter SH1 rotates around the axis AX1 according to the rotation of the rotary shaft RS1, and the shutter SH2 rotates around the axis AX1 according to the rotation of the rotary shaft RS2. The relative positions of the opening AP1, the opening AP2, and the target 320 change due to the rotation of the shutter SH1 and the shutter SH2. In this way, the target 320 is exposed to the stage 316 through the opening AP1 of the shutter SH1 and the opening AP2 of the shutter SH2 (refer to FIG. 10A), or shielded from the stage 316 by the shutter SH1 and the shutter SH2 (refer to FIG. 10B).

In the configuration shown in FIG. 10A, a film can be formed on the workpiece W. On the other hand, in the configuration shown in FIG. 10B, the substance which is discharged from the target 320 is shielded by the shutter SH1 and the shutter SH2 and is not deposited on the workpiece W.

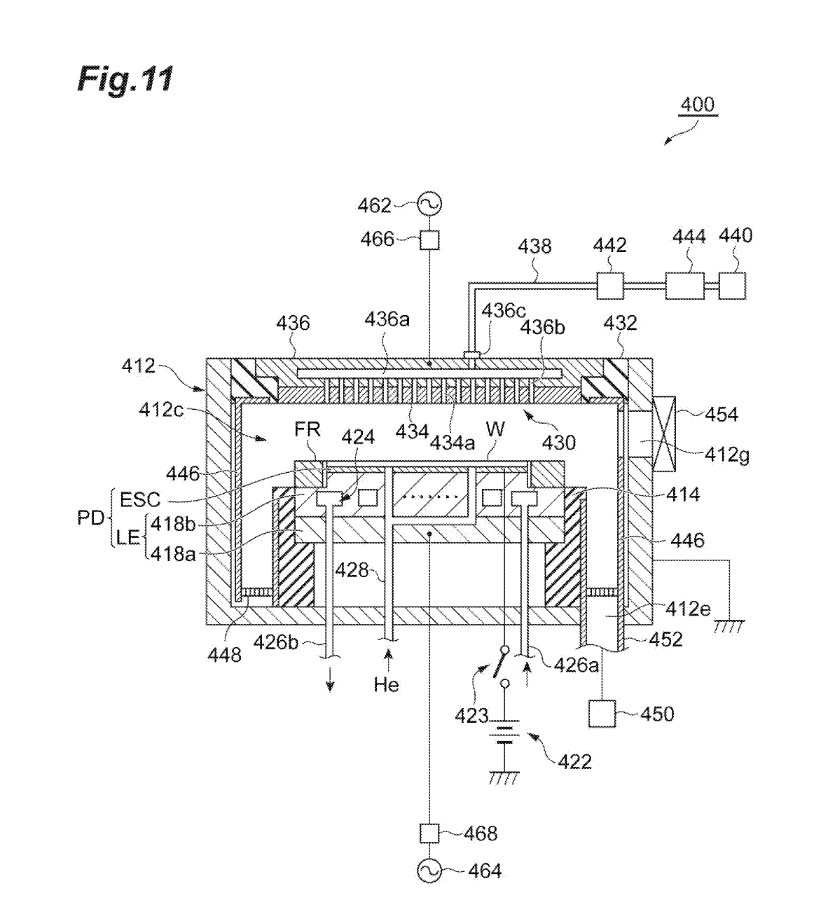

Hereinafter, a plasma processing apparatus which can be used as the fourth processing module 110h of the manufacturing system 100 will be described. FIG. 11 is a diagram illustrating the plasma processing apparatus which can be used as the fourth processing module. A plasma processing apparatus 400 shown in FIG. 11 is a capacitively coupled plasma processing apparatus. The plasma processing apparatus 400 is provided with a chamber body 412. The chamber body 412 provided its internal space as a chamber 412c. The chamber body 412 has a substantially cylindrical shape and is formed of, for example, aluminum. The inner wall surface of the chamber body 412 may be anodized. The chamber body 412 is grounded.

A support part 414 having a substantially cylindrical shape is provided on a bottom part of the chamber body 412. The support part 414 is configured of, for example, an insulating material. The support part 414 extends upward from the bottom part of the chamber body 412 in the chamber 412c. Further, a stage PD is provided in the chamber 412c. The stage PD is supported by the support part 414.

The stage PD holds the workpiece W on the upper surface thereof. The stage PD has a lower electrode LE and an electrostatic chuck ESC. The lower electrode LE includes a first plate 418a and a second plate 418b. Each of the first plate 418a and the second plate 418b is configured of metal such as aluminum, for example, and has a substantially disk shape. The second plate 418b is provided on the first plate 418a and electrically connected to the first plate 418a.

The electrostatic chuck ESC is provided on the second plate 418b. The electrostatic chuck ESC has an electrode built in a dielectric film. A direct-current power source 422 is electrically connected to the electrode of the electrostatic chuck ESC through a switch 423. The electrostatic chuck ESC attracts the workpiece W to the electrostatic chuck ESC by a Coulomb's force generated by the direct-current voltage from the direct-current power source 422 and holds the workpiece W.

A focus ring FR is disposed on a peripheral portion of the second plate 418b so as to surround an edge of the workpiece W and the electrostatic chuck ESC. The focus ring FR is provided in order to improve etching uniformity. The focus ring FR is configured of a material which is appropriately selected depending on a material of a film to be etched, and can be configured of, for example, quartz.

A flow path 424 is provided in the interior of the second plate 418b. A coolant is supplied from a chiller unit provided outside the chamber body 412 to the flow path 424 through a pipe 426a. The coolant supplied to the flow path 424 is returned to the chiller unit through a pipe 426b. In this manner, the coolant is circulated between the flow path 424 and the chiller unit. The temperature of the workpiece W supported by the electrostatic chuck ESC is controlled by controlling the temperature of the coolant.

Further, the plasma processing apparatus 400 is provided with a gas supply line 428. The gas supply line 428 supplies a heat transfer gas, for example, He gas, from a heat transfer gas supply mechanism to the space between the upper surface of the electrostatic chuck ESC and the back surface of the workpiece W.

Further, the plasma processing apparatus 400 is provided with an upper electrode 430. The upper electrode 430 is disposed above the stage PD so as to face the stage PD. The lower electrode LE and the upper electrode 430 are provided substantially parallel to each other. The upper electrode 430 is supported on an upper portion of the chamber body 412 through an insulating shielding member 432. The upper electrode 430 can include a ceiling plate 434 and a support 436. The ceiling plate 434 faces the chamber 412c. A plurality of gas injection holes 434a are provided in the ceiling plate 434. The ceiling plate 434 can be formed of, for example, silicon or SiC. Alternatively, the ceiling plate 434 can have a structure in which a ceramic coating is provided on the surface of a base material made of aluminum.

The support 436 detachably supports the ceiling plate 434 and can be configured of a conductive material such as aluminum, for example. A gas diffusion chamber 436a is provided in the interior of the support 436. A plurality of gas flow holes 436b communicating with the gas injection holes 434a extend downward from the gas diffusion chamber 436a. Further, a gas introduction port 436c for leading a processing gas to the gas diffusion chamber 436a is formed in the support 436, and a gas supply pipe 438 is connected to the gas introduction port 436c.

A gas source group 440 is connected to the gas supply pipe 438 through a valve group 442 and a flow rate controller group 444. The gas source group 440 includes one or more gas sources of a hydrogen-containing gas. The gas source group 440 may include a source of a rare gas in addition to the source of a hydrogen-containing gas.

The valve group 442 includes a plurality of valves, and the flow rate controller group 444 includes a plurality of flow rate controllers such as mass flow controllers. One or more gas sources of the gas source group 440 are respectively connected to the gas supply pipe 438 through corresponding valves of the valve group 442 and corresponding flow rate controllers of the flow rate controller group 444.

Further, in the plasma processing apparatus 400, a shield 446 is detachably provided along the inner wall of the chamber body 412. The shield 446 is also provided at the outer periphery of the support part 414. The shield 446 prevents an etching by-product from adhering to the chamber body 412 and can be configured by coating an aluminum material with ceramic such as Y₂O₃.

A baffle plate 448 is provided on the bottom part side of the chamber body 412 and between the support part 414 and the side wall of the chamber body 412. A plurality of through-holes penetrating in a plate thickness direction are formed in the baffle plate 448. The baffle plate 448 can be configured, for example, by coating an aluminum material with ceramic such as Y₂O₃. An exhaust port 412e is provided below the baffle plate 448 and in the chamber body 412. An exhaust device 450 is connected to the exhaust port 412e through an exhaust pipe 452. The exhaust device 450 has a vacuum pump such as a turbo molecular pump and can reduce the pressure in the chamber 412c to a desired degree of vacuum. Further, a transfer-in/transfer-out port 412g for the workpiece W is provided in the side wall of the chamber body 412, and the transfer-in/transfer-out port 412g can be opened and closed by a gate valve 454.

Further, the plasma processing apparatus 400 is further provided with a first high frequency power source 462 and a second high frequency power source 464. The first high frequency power source 462 is a power source for generating a first high frequency wave for plasma generation and generates the first high frequency wave having a frequency in a range of 27 to 100 MHz, for example. The first high frequency power source 462 is connected to the upper electrode 430 through a matching device 466. The matching device 466 has a circuit for matching the output impedance of the first high frequency power source 462 and the input impedance on the load side. The first high frequency power source 462 may be connected to the lower electrode LE through the matching device 466.

The second high frequency power source 464 is a power source for generating a second high frequency wave for attracting active species to the workpiece W, that is, for bias, and generates the second high frequency wave having a frequency in a range of 400 kHz to 13.56 MHz, for example. The second high frequency power source 464 is connected to the lower electrode LE through a matching device 468. The matching device 468 has a circuit for matching the output impedance of the second high frequency power source 464 and the input impedance on the load side.

In the plasma processing apparatus 400, a hydrogen-containing gas from the gas source group 440 is supplied into the chamber 412c. Further, the pressure in the chamber 412c is reduced. Further, the hydrogen-containing gas is excited in the chamber 412c by an electric field which is generated by the high frequency wave from the first high frequency power source 462. Accordingly, plasma is generated. Further, ions in the plasma are attracted to the workpiece W by the bias which is generated by the high frequency wave from the second high frequency power source 464. Therefore, in the plasma processing apparatus 400, it is possible to perform sputter etching on the workpiece W.

Hereinafter, an experiment performed for the evaluation of the manufacturing method MT will be described. In the experiment, by using the manufacturing system 100 described above, the underlying film IS was formed on the substrate SB, subsequently, plasma ashing was performed on the underlying film IS, subsequently, the multilayer film ML and the mask MK were formed on the underlying film IS, and subsequently, plasma etching on the multilayer film ML was performed. The conditions of each of the plasma ashing (the step ST2) and the plasma etching (the step ST4) are shown below. In the step ST4, plasma etching on the fifteenth layer L15 formed of Ru, plasma etching on the fourteenth layer L14 formed of Ta, and multilayer plasma etching from the thirteenth layer L13 to the first layer L1 were sequentially performed. In the multilayer plasma etching from the thirteenth layer L13 to the first layer L1, plasma etching using a first gas for 5 seconds and plasma etching using a second gas for 5 seconds were alternately repeated. The number of repetitions of the plasma etching using the first gas and the number of repetitions of the plasma etching using the second gas each were 25 times.

### <Conditions of the Step ST2>

Pressure in the chamber 212c: 150 mTorr (20 Pa)

O₂ gas flow rate: 280 sccm

Ar gas flow rate: 360 sccm

Microwave output: 3500 W

Stage temperature: 300° C.

Processing time: 300 seconds

### <Conditions of the Step ST4>

1. Plasma etching on the fifteenth layer L15 formed of Ru
Pressure in the chamber 412c: 10 to 30 mTorr (1.333 to 4 Pa)
H₂ gas flow rate: 100 sccm
N₂ gas flow rate: 50 sccm
Ne gas flow rate: 50 sccm to 250 sccm
Processing time: 100 seconds
Power of first high frequency wave: 200 W
Power of second high frequency wave: 0 W to 800 W
   2. Plasma etching on the fourteen layer L14 formed of Ta
Pressure in the chamber 412c: 10 to 30 mTorr (1.333 to 4 Pa)
Kr gas flow rate: 200 sccm
Processing time: 25 seconds
Power of first high frequency wave: 200 W
Power of second high frequency wave: 0 W to 800 W
   3. Multilayer plasma etching from the thirteenth layer L13 to the first layer L1
Pressure in the chamber 412c: 10 mTorr (1.333 Pa)
First gas
   CH₄ gas flow rate: 30 sccm
   Kr gas flow rate: 170 sccm
Second gas
   H₂ gas flow rate: 100 sccm
   N₂ gas flow rate: 50 sccm
   Ne gas flow rate: 50 sccm to 250 sccm
Power of first high frequency wave: 200 W
Power of second high frequency wave: 800 W

Further, for comparison, a comparative experiment was performed. In the comparative experiment, the processing equal to that in the above-described experiment except that the step ST2 was omitted was performed.

Then, a sample made by the experiment and a sample made by the comparative experiment were observed with an optical microscope. As a result, in the experiment in which processing which includes the step ST2 was performed, peeling and arcing of the multilayer film ML were not observed. On the other hand, in the comparative experiment, peeling and arcing of the multilayer film ML were observed. The usefulness of the manufacturing method MT was confirmed by these experimental results.

Hereinbefore, embodiments have been described above. However, various modifications can be made without being limited to the above-described embodiments. For example, the magnetoresistive device shown in FIG. 6 is a device having a MTJ (Magnetic Tunnel Junction) structure and is a device which is used for a magnetoresistive memory. However, the magnetoresistive device which is manufactured by the manufacturing method MT is not limited to a magnetoresistive device having the MTJ structure and may be a magnetoresistive device having a spin valve structure. Further, the magnetoresistive device which is manufactured by the manufacturing method MT is not limited to a device which is used for a magnetoresistive memory, and may be a device which is used for a magnetic head.

Further, in the second processing module 110b, instead of the plasma processing apparatus in which a gas is excited using microwaves, any type of plasma processing apparatus such as a capacitively coupled plasma processing apparatus or an inductively coupled plasma processing apparatus may be used. Further, in the fourth processing module 110h, instead of the capacitively coupled plasma processing apparatus, any type of plasma processing apparatus such as a plasma processing apparatus using a surface wave such as a microwave or an inductively coupled plasma processing apparatus may be used.

Further, although the fourth processing module 110h is connected to the transfer module 108 in the manufacturing system 100, the fourth processing module 110h may be separate from the transfer module 108.

From the foregoing description, it will be appreciated that various embodiments of the present disclosure have been described herein for purposes of illustration, and that various exemplary modifications may be made without departing from the scope and spirit of the present disclosure. Accordingly, the various exemplary embodiments disclosed herein are not intended to be limiting, with the true scope and spirit being indicated by the following claims.

What is claimed is:

1. A method of manufacturing a magnetoresistive device comprising:
forming an underlying film including silicon, oxygen, and carbon, on a substrate;
performing plasma ashing on the underlying film by using plasma of an oxygen-containing gas;
forming a multilayer film including a metal layer and a magnetic layer, on the underlying film subjected to ashing; and
performing plasma etching on the multilayer film by using plasma of a hydrogen-containing gas.

2. The method of manufacturing a magnetoresistive device according to claim 1, wherein the underlying film is formed by a chemical vapor deposition method using a gas containing silicon and carbon.

3. The method of manufacturing a magnetoresistive device according to claim 2, wherein the gas containing silicon and carbon includes tetraethoxysilane or methylsilane.

4. The method of manufacturing a magnetoresistive device according to claim 1, wherein the hydrogen-containing gas includes at least one of H₂, H₂O, a hydrocarbon, an alcohol, a ketone, an aldehyde, and a carboxylic acid.

5. The method of manufacturing a magnetoresistive device according to claim 1, wherein the metal layer includes ruthenium or platinum.

6. A magnetoresistive device manufacturing system comprising:
a transfer module having a transfer chamber capable of being depressurized and a transfer apparatus provided in the transfer chamber to transfer a substrate;
a first processing module configured to form an underlying film including silicon, oxygen, and carbon, on the substrate;
a second processing module configured to perform plasma ashing on the underlying film by using plasma of an oxygen-containing gas;
a plurality of third processing modules configured to form a multilayer film including a metal layer and a magnetic layer,
a fourth processing module configured to perform plasma etching on the multilayer film by using plasma of a hydrogen-containing gas; and
a controller configured to control the first processing module, the second processing module, the plurality of third processing modules, and the fourth processing module,
wherein the first processing module, the second processing module, the plurality of third processing modules, and the fourth processing module are connected to the transfer module, and
the controller is configured to control the transfer apparatus, the first processing module, the second processing module, the plurality of third processing modules, and the fourth processing module so as to form the underlying film on the substrate, perform the plasma ashing on the underlying film, form the multilayer film on the underlying film subjected to ashing, and perform the plasma etching on the multilayer film, and control the transfer apparatus so as to transfer a workpiece having the underlying film subjected to ashing to a processing module for forming a lowermost layer of the multilayer film, among the plurality of third processing modules, through only a depressurized space including the transfer chamber, after the plasma ashing.
